(19) United States
(12) Patent Application Publication
(10) Pub. No.: US 2004/0245600 A1
(43) Pub. Date: Dec. 9, 2004

(54) Semiconductor device and its manufacturing method

(76) Inventor: Toshiyuki Kamiya, Nagano-ken (JP)

Correspondence Address: HARNESS, DICKEY & PIERCE, P.L.C., P.O. BOX 828, BLOOMFIELD HILLS, MI, 48303, US

(21) Appl. No.: 10/812,408

(22) Filed: Mar. 26, 2004

(30) Foreign Application Priority Data
Mar. 31, 2003 (JP) 2003-095973

(51) Int. Cl. H01L 29/04

(52) U.S. Cl. 257/529

(57) ABSTRACT

A semiconductor device is provided including a first protection film and a second protection film which are stacked in layers in this order on an upper surface of a fuse that includes an upper layer wiring layer. An opening section is formed in the first and second protection films. The opening section exposes an entire portion of the first protection film located directly above the fuse.

### RELATED APPLICATIONS

This application claims priority to Japanese Patent Application No. 2003-095973 filed Mar. 31, 2003 which is hereby expressly incorporated by reference herein in its entirety.

### BACKGROUND

1. Technical Filed of the Invention

The present invention relates to semiconductor devices and methods for manufacturing the same, and more particularly to a technology that is effective in improving the reliability of fuses that compose redundant circuits.

2. Conventional Technology

In conventional semiconductor devices, a technique to use wiring layers in an upper layer as fuses has been proposed. Generally, fuses are covered by a protection film in order to secure their reliability.

FIGS. 3(a)-(b) show an example of the composition of a conventional semiconductor device, in which FIG. 3(a) is a plan view and FIG. 3(b) is a cross-sectional view taken along line B-B of FIG. 3(a).

As indicated in FIGS. 3(a)-(b), the conventional semiconductor device is composed of, on an upper surface of a semiconductor substrate 11 having specified semiconductor elements (not shown) formed therein, a first lower layer wiring layer 13 composed of polysilicon or the like formed through a dielectric layer 12 composed of silicon oxide or the like, a second lower layer wiring layer 15 formed through a first interlayer dielectric layer 14 composed of silicon oxide or the like above the first lower layer wiring layer 13, and an upper layer wiring layer 17 composed of Al or the like formed through a second interlayer dielectric layer 16 composed of silicon oxide or the like above the second lower layer wiring layer 15, wherein the upper layer wiring layer 17 functions as a fuse. It is noted that a code C in FIG. 3(b) indicates a contact hole that connects the first lower layer wiring layer 13 and the second lower layer wiring layer 15, and similarly, a code V indicates a via hole that connects the upper layer wiring layer 17 and the second lower layer wiring layer 15.

Also, the upper layer wiring layer 17 is covered by a first protection film 18 composed of silicon oxide or the like deposited on its upper surface, and a second protection film 19 composed of silicon nitride or the like. The second protection film 19 defines an opening section 10H formed therein that exposes a portion of the first protection film 18 directly above the upper layer wiring layer 17 that functions as a fuse.

There is a known technology in which a laser beam is irradiated through the opening section 10H formed in the second protection film 19 to irradiate the first protection film 18 formed directly above the upper layer wiring layer 17 that functions as a fuse, to thereby melt (cut) the fuse (for example, see Japanese Laid-open Patent Application HEI 5-29467)

Here, the melting of the fuse can be achieved by irradiating a portion of the first protection film 18 that is formed directly above the upper layer wiring layer 17 that functions as a fuse. In other words, the opening section 10H for the fuse-melting purpose formed in the second protection film 19 may be acceptable if it is at least larger than the light diameter of a laser beam to be irradiated through the opening section 10H. Currently, no particular consideration is given to the size of the opening area and the opening position of the opening section 10H.

For this reason, even in the invention described in Japanese Laid-open Patent Application HEI 5-29467, an opening section 10H formed in the second protection film 19 is formed in a manner that an interior of a region thereof that contains a part of the first protection film 18 formed directly above the upper layer wiring layer 17 is exposed, and a bottom end section of the opening section 10H exists at positions above the upper layer wiring layer 17. In other words, the walls of the opening section 10H are inboard the ends of the upper layer wiring layer 17.

However, the present inventor discovered a problem in the semiconductor device described in Japanese Laid-open Patent Application HEI 5-29467 in that, at the stage in a step of packaging semiconductor elements, the first protection film 18 that is exposed at a bottom of the opening section 10H is stressed, such that cracks CK are generated in the protection film 18 particularly at positions located at bottom end sections of the opening section 10H (where the bottom and the walls meet).

Further, the present inventor has found a problem in that water content in the atmosphere enters the cracks CK in the first protection film 18 and reaches its underlayer, i.e., the upper layer wiring layer 17, such that erosions 17A occur in the fuse composed of the upper layer wiring layer 17, and the reliability of the fuse lowers. In particular, along with the recent trend of higher integration and lower power consumption of semiconductor devices, the number of fuses required on each semiconductor integrated circuit has substantially increased, such that deficiencies of fuse sections may possibly substantially lower the reliability of the semiconductor integrated circuit.

Accordingly, the present invention has been made in view of the circumstances described above, and one object is to provide a semiconductor device and its manufacturing method, which can improve the reliability of fuses.

### SUMMARY

The present inventor has made keen examinations to solve the above problems, and discovered that the problems can be solved by forming an opening section to be formed in a second protection film in a manner that its bottom end section is not located above a fuse composed of an upper layer wiring layer.

More specifically, a semiconductor device in accordance with the present invention comprises a first protection film and a second protection film deposited in layers in this order on an upper surface a fuse composed of an upper layer wiring layer, the second protection film defining an opening section formed therein that exposes the first protection film, wherein the opening section is formed such that, within the first protection film, an interior of a region thereof containing an entire portion located directly above the fuse is exposed.

Here, in the semiconductor device in accordance with the present invention, each of two end sections of the fuse may preferably be connected to a lower layer wiring layer through a via hole.

A method for manufacturing a semiconductor device in accordance with the present invention comprises: a step of forming a fuse composed of an upper layer wiring layer on an upper surface of an interlayer dielectric layer that is formed on a substrate; a step of forming a first protection film on an upper surface of the interlayer dielectric layer and the fuse; a step of forming a second protection film on an upper surface of the first protection film; and a step of forming an opening section in the second protection film such that, within the first protection film, a region thereof containing an entire portion located directly above the fuse is exposed.

Here, the method for manufacturing a semiconductor device in accordance with the present invention may preferably include the steps of forming via holes in the interlayer dielectric layer, and connecting two ends of the fuse to a lower layer wiring layer through the via holes.

In this manner, in the semiconductor device in accordance with the present invention, by forming the opening section to be formed in the second protection film in a manner that, within the first protection film, an interior of a region thereof that contains an entire portion located directly above the fuse is exposed, bottom end sections of the opening section are not located above the fuse. Accordingly, even if cracks are generated in the first protection film at the bottom end sections of the opening section, the possibility of the cracks contacting the upper surface of the fuse can be substantially reduced. Consequently, erosions of the fuse can be controlled, and the reliability of the fuse can be substantially improved.

Also, in the semiconductor device in accordance with the present invention, due to the fact that the two end sections of the fuse are connected to a lower layer wiring layer through via holes, erosions of the fuse can be readily and securely suppressed, and the reliability of the fuse can be substantially improved by forming the opening section to be formed in the second protection film in a manner that an interior of a region that contains the entire portion of the first protection film that is located directly above the fuse is exposed.

By the method for manufacturing a semiconductor device in accordance with the present invention, the semiconductor device in accordance with the present invention can be readily realized.

### BRIEF DESCRIPTION OF THE DRAWINGS

FIGS. 1(a) and (b) show an example of the structure of a semiconductor device in accordance with the present invention, in which FIG. 1 (a) is a plan view and FIG. 1(b) is a cross-sectional view taken along line A-A of FIG. 1(a).

FIGS. 2(a)-(c) show cross sections illustrating a method for manufacturing a semiconductor device in accordance with the present invention.

FIGS. 3(a)-(b) show an example of the structure of a conventional semiconductor device, in which FIG. 3(a) is a plan view and FIG. 3(b) is a cross-sectional view taken along line B-B of FIG. 3(a).

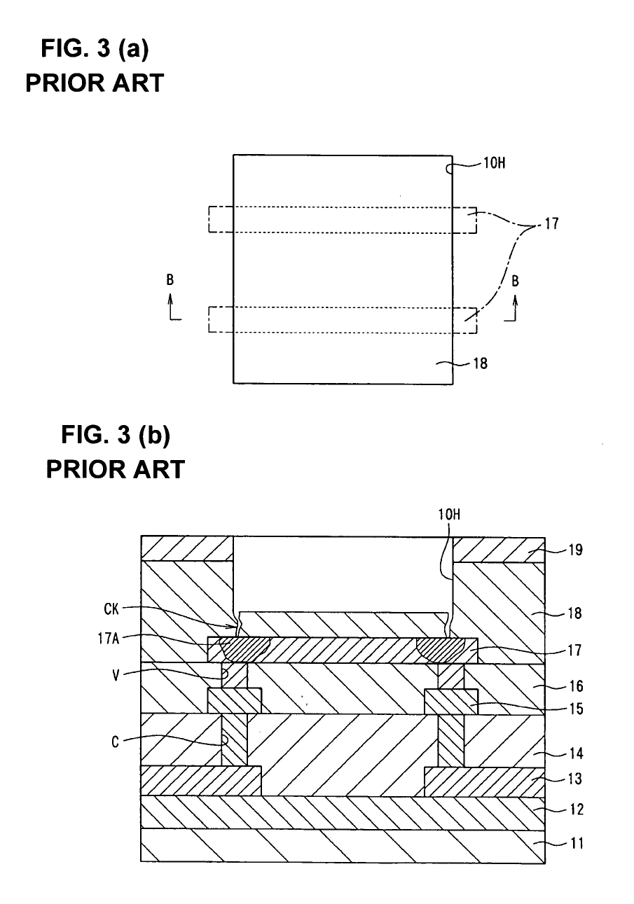

### DETAILED DESCRIPTION

An embodiment of the present invention will be described below with reference to the accompanying drawings. It is noted that the present embodiment shows one example of the present invention, and the present invention is not limited to the present embodiment.

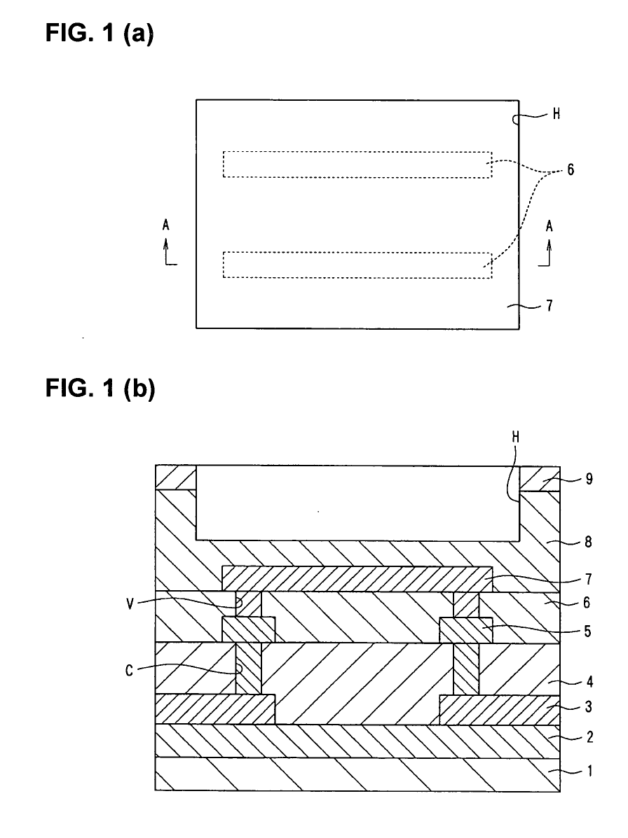

FIGS. 1(a)-(b) show an example of the structure of a semiconductor device of the present invention, in which FIG. 1(a) is a plan view and FIG. 1(b) is a cross-sectional view taken along line A-A of FIG. 1(a).

As shown in FIGS. 1(a)-(b), the semiconductor device in accordance with the present embodiment has a structure in which, on an upper surface of a semiconductor substrate 1 having specified semiconductor elements (not shown) formed therein, a dielectric layer 2, first lower layer wiring layers 3, a first interlayer dielectric layer 4, second lower layer wiring layers 5 that are connected to the first lower layer wiring layers 3 through contact holes C formed in the first interlayer dielectric layer 4, a second interlayer dielectric layer 6, an upper layer wiring layer 7 that is connected to the second lower layer wiring layers 5 through via holes V formed in the second interlayer dielectric layer 6, a first protection film 8 and a second protection film 9, are successively stacked in layers, wherein the upper layer wiring layer 7 functions as a fuse.

The second protection film 9 defines an opening section H formed therein that exposes, within the first protection film 8 at the lower layer, a region thereof containing in its interior an entire portion located directly above the upper layer wiring layer 7. By irradiating a laser beam through the opening section H, the first protection film 8 formed directly above the upper layer wiring layer 7 that functions as a fuse is irradiated, to thereby melt and cut the fuse. In other words, the opening section H has a width which is greater than a width of the upper layer wiring layer 7 so that the walls of the opening section H lie outboard the ends of the upper layer wiring layer 7. Importantly, the bottom end portions of the opening section H where the walls and the bottom of the opening section H meet are outboard of (laterally offset) from the upper layer wiring layer 7.

The upper layer wiring layer 7 that functions as a fuse has a structure in which, on the second interlayer dielectric layer 6, a wiring layer formed from electrode forming material such as metal material such as Al, Cu or the like or a polysilicon material, and a dielectric layer formed from a silicon oxide film or the like are successively deposited in layers.

The first protection film 8 is formed from, for example, a silicon oxide film deposited by a plasma CVD method on the upper layer wiring layer 7.

The second protection film 9 is formed from, for example, a silicon nitride film deposited by a plasma CVD method.

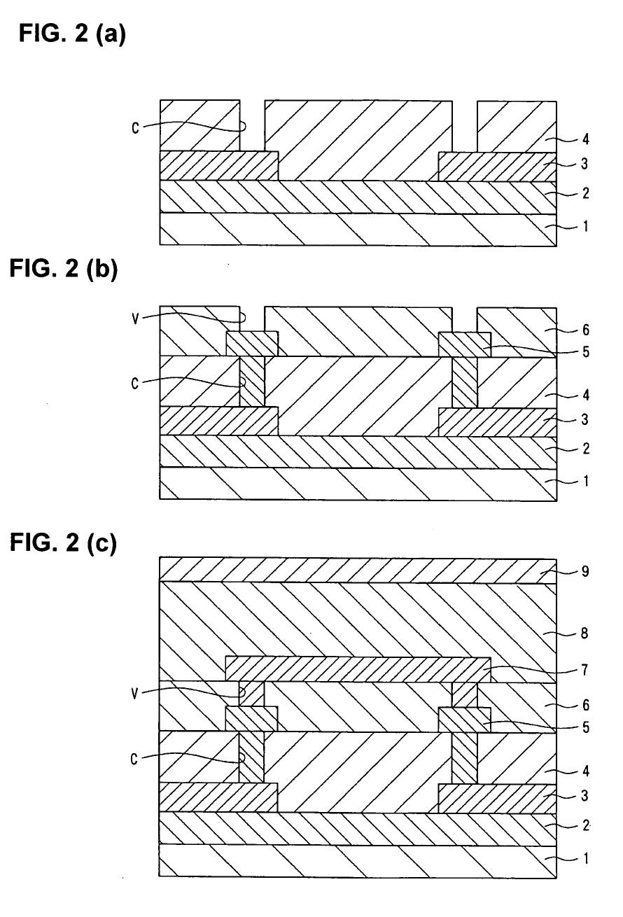

Next, a method for manufacturing a semiconductor device in accordance with an embodiment of the present invention will be described. FIGS. 2(a)-(c) show cross sections illustrating a method for manufacturing a semiconductor device in accordance with the present invention.

First, as indicated in FIG. 2(a), a silicon oxide film for a dielectric layer 2 and a polysilicon film for first lower layer wiring layers 3 are successively deposited on a semiconductor substrate 1, by using a known wet oxidation method. Then, a known photolithography technique and etching technique are used to form the dielectric layer 2 and the first lower layer wiring layers 3 in specified shapes.

Then, a first interlayer dielectric layer 4 composed of a silicon oxide film is formed by using a known CVD method over the entire surface of the semiconductor substrate 1 where the dielectric layer 2 and the first lower layer wiring layers 3 are formed.

Then, by using known photolithography technique and etching technique, contact holes C that reach the first lower layer wiring layers 3 are formed in the first interlayer dielectric layer 4.

Then, as indicated in FIG. 2(b), an aluminum film for second lower layer wiring layers 5 is formed over the entire surface of the first interlayer dielectric layer 4 having the contact holes C formed therein by using a known sputter method; and then the second lower layer wiring layers 5 in specified shapes are formed by using known photolithography technique and etching technique.

Then, a second interlayer dielectric layer 6 composed of a silicon oxide film is formed by using a known CVD method over the entire surface of the semiconductor substrate 1 having the second lower layer wiring layers 5 formed therein.

Then, by using known photolithography technique and etching technique, via holes V that reach the second lower layer wiring layers 5 are formed in the second interlayer dielectric layer 6.

Then, as indicated in FIG. 2(c), an aluminum film for an upper layer wiring layer 7 is formed by using a known sputter method over the entire surface of the second interlayer dielectric layer 6 having the via holes V formed therein; and thereafter by using known photolithography technique and etching technique, the upper layer wiring layer 7 in a specified shape is formed.

Then, a first protection film 8 composed of a silicon oxide film is formed by using a known plasma CVD method over the entire surface of the semiconductor substrate 1 having the upper layer wiring layer 7 formed therein.

Then, a second protection film 9 composed of a SiN film is formed by using a known CVD method on the first protection film 8.

Then, by using a known photolithography technique, a mask is formed on an upper surface of the second protection film 9 in a manner that, within the first protection film 8 at its lower layer, an entire portion located directly above the upper layer wiring layer 7 is to be exposed, and in this state, etching is conducted up to an intermediate point in the first protection film 8 in its depth direction. In this instance, there is formed in the second protection film 9 an opening section H that exposes inside thereof, within the first protection film 8 at the lower layer, an entire portion located directly above the upper layer wiring layer 7. That is, the width of the opening section H is at least equal to a width of the upper layer wiring layer 7. Further, the depth of the opening section H is controlled. In this instance, the etching condition may preferably be determined such that the film thickness of the first protection film 8 that remains at the bottom of the opening section H is about 350 nm in order that the fuse can be securely melted.

In this manner, in the semiconductor device in accordance with the present embodiment, the opening section H for fuse-melting to be formed in the second protection film 9 is formed in a manner that, within the first protection film 8, an entire portion located directly above the fuse composed of the upper layer wiring layer 7 is exposed inside of the opening section H. Accordingly, even if cracks are generated in the first protection film 8 at the bottom end sections of the opening section H in a process of packaging the semiconductor device, the possibility of the cracks contacting the upper surface of the upper layer wiring layer 7 can be substantially reduced. Consequently, erosions of the fuse can be suppressed, and the reliability of the fuse can be substantially improved.

Also, in the semiconductor device in accordance with the present embodiment, due to the fact that the two end sections of the fuse composed of the upper layer wiring layer 7 are respectively connected to the second lower layer wiring layers 5 through the via holes V, erosions of the fuse can be suppressed, and the reliability of the fuse can be improved by forming the opening section H to be formed in the second protection film 9 to match with the measurements of the fuse composed of the upper layer wiring layer 7.

It is noted that, in the semiconductor device in accordance with the present embodiment described above, the film thickness of the first protection film 8 that is to remain directly above the fuse is adjusted in the etching process for forming the opening section H for fuse-melting. However, the method for adjusting the film thickness of the first protection film 8 that is to remain directly above the fuse is not limited to this embodiment. For example, in the process of forming the first protection film 8 over an upper surface of the fuse, a film having a film thickness of a predetermined measurement may be formed; and in the process of forming the opening section H for fuse-melting, only the second protection film 9 may be etched to form the opening section H.

Also, in the present embodiment described above, the upper layer wiring layer 7 is an uppermost layer wiring layer. However, without being limited to this embodiment, an uppermost layer wiring layer may be formed through an interlayer dielectric layer over an upper surface of the upper layer wiring layer 7 that composes the fuse.

What is claimed is:

1. A semiconductor device comprising:
a fuse including an upper layer wiring layer;
a first protection film on the fuse; and
a second protection film on the first protection film, the second protection film including an opening section formed therein that exposes the first protection film;
the opening section exposing an entire portion of the first protection film located directly above the fuse.

2. A semiconductor device according to claim 1, wherein each of two end sections of the fuse is connected to a lower layer wiring layer through a via hole.

3. A method for manufacturing a semiconductor device, comprising:
a step of forming a fuse including of an upper layer wiring layer on an upper surface of an interlayer dielectric layer that is formed on a substrate;
a step of forming a first protection film on an upper surface of the interlayer dielectric layer and the fuse;
a step of forming a second protection film on an upper surface of the first protection film; and
a step of forming an opening section in the second protection film, the opening section exposing an entire portion of the first protection film located directly above the fuse.

4. A method for manufacturing a semiconductor device according to claim 3, further comprising the steps of forming via holes in the interlayer dielectric layer, and connecting two ends of the fuse to a lower layer wiring layer through the via holes.

5. A semiconductor device comprising:
a substrate;
a fuse disposed on the substrate, the fuse including an upper layer wiring layer;
a first protection film disposed on the fuse; and
a second protection film disposed on the first protection film, the second protection film including an opening formed therein exposing the first protection film;
the opening section having a width at least equal to a width of the fuse.

6. The semiconductor device of claim 5 wherein said opening section extends outboard of said fuse.

7. The semiconductor device of claim 5 wherein said opening section includes bottom end portions outboard of said fuse.
